(19) United States
(12) Patent Application Publication
(10) Pub. No.: US 2005/0258541 A1
(43) Pub. Date: Nov. 24, 2005

(54) Semiconductor device and manufacturing method thereof

(76) Inventor: Hidekazu Yanagisawa, Sakata (JP)

Correspondence Address: HARNESS, DICKEY & PIERCE, P.L.C., P.O. BOX 828, BLOOMFIELD HILLS, MI, 48303, US

(21) Appl. No.: 11/126,975

(22) Filed: May 11, 2005

(30) Foreign Application Priority Data
May 18, 2004 (JP) 2004-148055

(51) Int. Cl. H01L 23/48

(52) U.S. Cl. 257/751

(57) ABSTRACT

A semiconductor device and a manufacturing method thereof are provided. In a barrier metal, a first layer Ti film is set to a (002) crystal plane with a high orientation, and a second layer TiN film is thinner than the first layer Ti film, and takes a pattern that inherits the effect of the (002) crystal orientation of the first layer Ti film. An aluminum layer on the barrier metal is dependent on the orientation of either the second layer TiN film or the first layer Ti film under the second layer TiN film, and takes a pattern that is controlled with a high orientation to the (111) crystal plane. On the aluminum layer, another TiN film is formed as an anti-reflection film.

### RELATED APPLICATIONS

This application claims priority to Japanese Patent Application No. 2004-148055 filed May 18, 2004 which is hereby expressly incorporated by reference herein in its entirety.

### BACKGROUND

1. Technical Field

The present invention relates to a metal wiring technique of a semiconductor integrated circuit, particularly to a semiconductor device and a manufacturing method thereof, having a highly integrated aluminum wiring structure.

2. Related Art

In integrated circuit wirings of semiconductor devices, aluminum-based metal wirings are common. Features such as a barrier metal or an anti-reflection film for preventing spikes are collateral to the wiring, hence the wiring is not a single layer, but a multi layer. At the same time, in enhancing the electromigration resistance, it is an important provision to have the crystal direction of crystal grains that construct an aluminum wiring to be (111)-oriented, as well as to make crystal grain size large and with a reduced fluctuation, etc.

In the above mentioned metal wiring, titanium (Ti)/titanium nitride (TiN) deposited film, for example, is formed as a barrier metal, and above it a substantial aluminum (Al)-based metal wiring is formed. On the top layer, an anti-reflection TiN film is installed in order to improve the lithography fabrication accuracy. For metal wiring, Al-based structures that contain very small quantities of Cu or Si, such as Al—Cu structure, Al—Si structure, and Al—Si—Cu structure, are known.

TiN and Al have the same face-centered cubic structure (FCC) and the close lattice constants, thus there is a characteristic that an Al (111) crystal plane grows in coordinate with a TiN (111) crystal plane. However, conventionally, TiN is deposited either with the reactive sputtering method or put through a nitriding processing after a Ti sputtering. For this reason, a uniform thin-film formation is problematic with TiN, and its adhesive property is poor. That is to say, when trying to form a TiN thin film that does not impact a wiring resistance as much as possible, it is difficult to form a (111) crystal plane uniformly. Consequently, not only that it is not possible to align a (111) crystal plane uniformly, but further, in the worst case, it may not be possible to maintain its feature as a barrier.

Moreover, in conventional art, a technology of controlling a crystal orientation of an upper layer film, by regulating a surface roughness (Ra) of a lower layer film to a specific range such as 10 nm or less, is disclosed. For example, employing a tungsten film, in other words a CVD-W film deposited with a CVD (Chemical Vapor Deposition), a surface roughness (Ra) of the CVD-W film is controlled to be 10 nm or less. This enables materialization of an Al (111) crystal orientation when formed as an upper layer film, even though in a CVD-W film, there are two kinds of crystal direction mixed in a body-centered cubic structure (BCC). For example, refer to Japanese Unexamined Patent Publication No. 2001-53598.

As mentioned above, since it is problematic to form a TiN thin film uniformly by employing a sputter technique, as well as due to its poor adhesive property, it is difficult to align an Al (111) crystal plane of an upper layer film. Moreover, in a technology of materializing an Al (111) crystal orientation of an upper layer film by employing a surface-roughness (Ra) controlled CVD-W film, there is a cost problem since the existing processes need to be modified, such as the etching process, etc.

The present invention, in light of the above-mentioned circumstances, is intended to provide the semiconductor device and the manufacturing method thereof, which forms a thin-film barrier metal that does not affect neither an existing process nor a wiring resistance as much as possible, and has an aluminum-based highly reliable wiring structure which sets a (111) crystal plane with a high orientation.

### SUMMARY

The semiconductor device in the present invention, comprises: a wiring member that constitutes an integrated circuit in relation to multiple elements formed on a semiconductor substrate; wherein the wiring member comprises an aluminum-based conductive layer with a barrier metal layer including, a titanium film as a first layer, with a high orientation to a (002) crystal plane, and a buffer film as a second layer that inherits the orientation of the titanium film as well as having a film thickness that prevents diffusion or alloying, where the conductive layer is controlled with a high orientation to a (111) crystal plane.

According to the manufacturing method of a semiconductor device in the present invention, a buffer film is formed on a Ti film with a crystal orientation to the (002) face, without deforming the crystallographic information of the Ti film. An aluminum-based conductive layer is dependent on the orientation of either the buffer film or the Ti film under the buffer film, and takes a pattern that is controlled with a high orientation to the (111) crystal plane. Consequently, there is a contribution to the improvement of the electromigration resistance.

The semiconductor device in the present invention, comprises: a wiring member that constitutes an integrated circuit in relation to multiple elements formed on a semiconductor substrate; wherein the wiring member comprises an aluminum-based conductive layer with a barrier metal layer including a titanium film as the first layer having a (002) crystal plane, and a titanium nitride film as the second layer formed by the chemical vapor deposition method, of which thickness is smaller than that of the titanium film, where the conductive layer is controlled with a high orientation to a (111) crystal plane.

According to the semiconductor device in the present invention, the TiN film, formed with CVD method, is formed on the Ti film with a crystal orientation to the (002) face. This TiN film has a desirable step coverage feature, and unlike a sputter-deposited film, while it is thin, it is sufficiently uniform, and thus it can be a buffer film that prevents diffusion or alloying. An aluminum-based conductive layer is dependent on the orientation of either the TiN film or the Ti film under the TiN film, and takes a pattern that is controlled with a high orientation to the (111) crystal plane. Consequently, there is a contribution to the improvement of the electromigration resistance.

The semiconductor device in the present invention, comprises: a wiring member that constitutes an integrated circuit in relation to multiple elements formed on a semiconductor substrate; wherein the wiring member comprises an aluminum-based conductive with a barrier metal layer including a titanium film as the first layer having a crystal orientation to a (002) face, and a titanium nitride film as the second layer that inherits the orientation of the titanium film, where the conductive layer is controlled with a high orientation to a (111) crystal plane that is affected by the orientation of the titanium film.

According to the semiconductor device in the present invention, the TiN film that inherits the orientation of the Ti film is formed on the Ti film with a crystal orientation to the (002) face. The orientation of the TiN (111) crystal plane is extremely similar to the atomic arrangement of the Ti (002) crystal plane. Consequently, crystallographic information is inherited from the first Ti film to the second TiN film. This TiN film needs a thickness to function as a buffer film that at the very least prevents diffusion or alloying. An aluminum-based conductive layer is dependent on the orientation of either the TiN film or the Ti film under the TiN film, and takes a pattern that is controlled with a high orientation to the (111) crystal plane. Consequently, there is a contribution to the improvement of the electromigration resistance.

Moreover, in the respective aforementioned semiconductor device in the present invention comprises: an interlayer insulation film; and a hole that penetrates through the insulation film and exposes a conductive base; wherein the wiring member is formed on the insulation film and on the hole.

Further, in the respective aforementioned semiconductor devices in the present invention comprises: an interlayer insulation film; a hole that penetrates through the insulation film and exposes a conductive base; and a connecting plug buried in the hole; wherein the wiring member is formed on the insulation film and on the connecting plug.

The method of manufacturing the semiconductor device in the present invention includes: a method of manufacturing a semiconductor device that forms a wiring member that relates to multiple elements on a given layer of a semiconductor substrate, wherein for the wiring member, the method of manufacturing the semiconductor device comprising the steps of: forming a titanium film as a first layer of a barrier metal with a high orientation to a (002) crystal plane; forming a buffer film that prevents diffusion or alloying as a second layer of the barrier metal so that an orientation of the titanium film is inherited; and forming an aluminum-based conductive layer on the buffer film as a main part of the wiring member, that is controlled with a high orientation to a (111) crystal plane by, at the very least, being affected by the orientation of the titanium film.

According to the manufacturing method of a semiconductor device in the present invention, the crystal orientation of the Ti film is set to the (002) face with a high orientation, and over it, the buffer film is formed so as to inherit the crystallographic information of the Ti film. An aluminum-based conductive layer is dependent on the orientation of either the buffer film or the Ti film under the buffer film, and takes a pattern that is controlled with a high orientation to the (111) crystal plane. Consequently, there is a contribution to the improvement of the electromigration resistance.

Further, it is desirable for the manufacturing method of the above-mentioned semiconductor device to have any of the following features, and the method contributes to the conservation of the existing process or to the reliability improvement.

A sputtering method is used for the titanium film.

The titanium nitride film is formed with a chemical vapor deposition method for the buffer film.

The titanium nitride film that is thinner than the titanium film is formed for the buffer film.

### BRIEF DESCRIPTION OF THE DRAWINGS

FIG. 1 is a sectional drawing that shows the stacked structure of the metal wiring of the semiconductor device in the first embodiment of the present invention.

FIG. 2 is a flow chart that shows the manufacturing method of the semiconductor device in the configuration of FIG. 1.

FIG. 3 is a magnified surface drawing that shows the aluminum wiring structure, comparing the conventional one and that of the present invention.

FIG. 4 is a sectional drawing that shows the stacked structure of the metal wiring of the semiconductor device in the second embodiment of the present invention.

FIG. 5 is a sectional drawing that shows the mid-flow process of the manufacturing method of the semiconductor device in the configuration of FIG. 4 (or FIG. 1).

### DETAILED DESCRIPTION

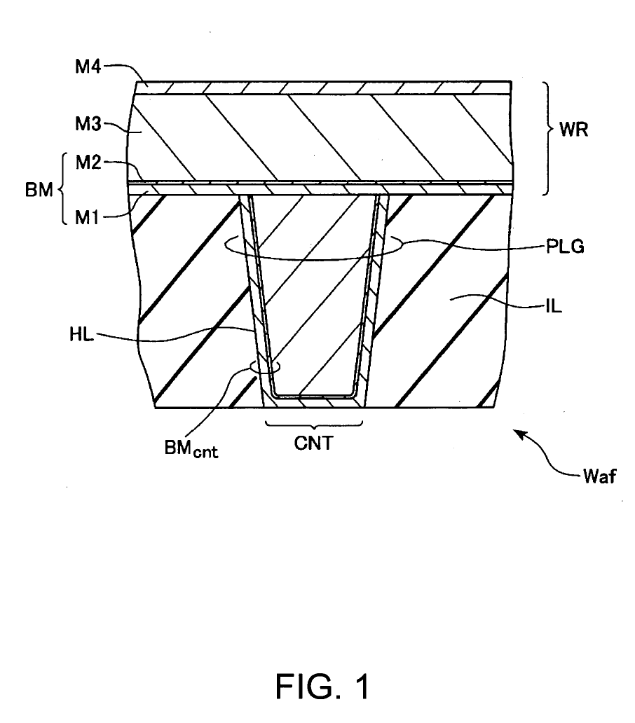

FIG. 1 is a sectional drawing that shows the stacked structure of the metal wiring in the first embodiment of the present invention. A metal wiring WR, in relation to multiple elements (not shown) formed on a semiconductor substrate Waf, constitutes an integrated circuit. For example, the metal wiring WR is composed so as to be patterned on a interlayer insulation film IL having a barrier metal BM as a foundation, as well as to be connected to a connecting part CNT at a lower layer. The connecting part CNT is a conductive part on the diffusion layer of a semiconductor substrate or on the semiconductor substrate, which is not shown. The connecting part CNT is electrically connected to the metal wiring WR through a metal plug PLG that includes a barrier metal BMcnt at a hole HL installed in the interlayer insulation film IL.

In the present invention, what is particularly important is the orientation of the bottom layer of the metal wiring WR, the barrier metal BM. The barrier metal BM has the buffer films on an adhesive layer as well as over the adhesive layer that prevents diffusion or alloying. Here, the barrier metal BM adopts a first layer Ti film M1 as the adhesive layer, and a second layer TiN film M2 as a buffer layer. On the barrier metal BM, an aluminum layer M3 is formed as the Al-based conductive part. Here, the aluminum layer M3 has an Al—Cu structure that contains, for example, a very small quantity of Cu (about 0.5%) in the aluminum.

The first layer Ti film MI of the barrier metal BM is set to the (002) crystal plane with a high orientation. Here, the term “crystal plane with a high orientation”, means that the given crystal plane is controlled to be in the orientation ratio of 80% or more. That is to say, the Ti film M1 is composed so that the (002) crystal plane resides in a high orientation ratio (80% or more) against the foundation. The second layer TiN film M2 of the barrier metal BM inherits the orientation of the Ti film M1, and is set to the (111) crystal plane with a high orientation. The orientation of the TiN (111) crystal plane is extremely similar to the atomic arrangement of the Ti (002) crystal plane. Consequently, crystallographic information is inherited from the first Ti film M1 by the second TiN film M2.

Here, the TiN film M2 is the CVD-TiN film formed to be thin by employing the chemical vapor deposition method. While the thickness of the Ti film M1 is around 10 to 20 nm, the thickness of the TiN film M2 is thinner than that of the Ti film M1, around 5 to 10 nm. Since the TiN film M2 is extremely thin, there is a possibility that the (111) crystal plane will not emerge, but, at the very least, it takes a pattern that inherits the effect of the (002) crystal plane orientation of the Ti film M1.

On the barrier metal BM, the aluminum layer M3 is formed in the thickness of around 300 to 500 nm. The aluminum layer M3 is dependent on the orientation of either the TiN film M2 or the Ti film M1 under the TiN film M2, and takes a pattern that is controlled with a high orientation to the (111) crystal plane. On the aluminum layer M3, a TiN film M4 is formed with a thickness of around 30 nm as an anti-reflection film.

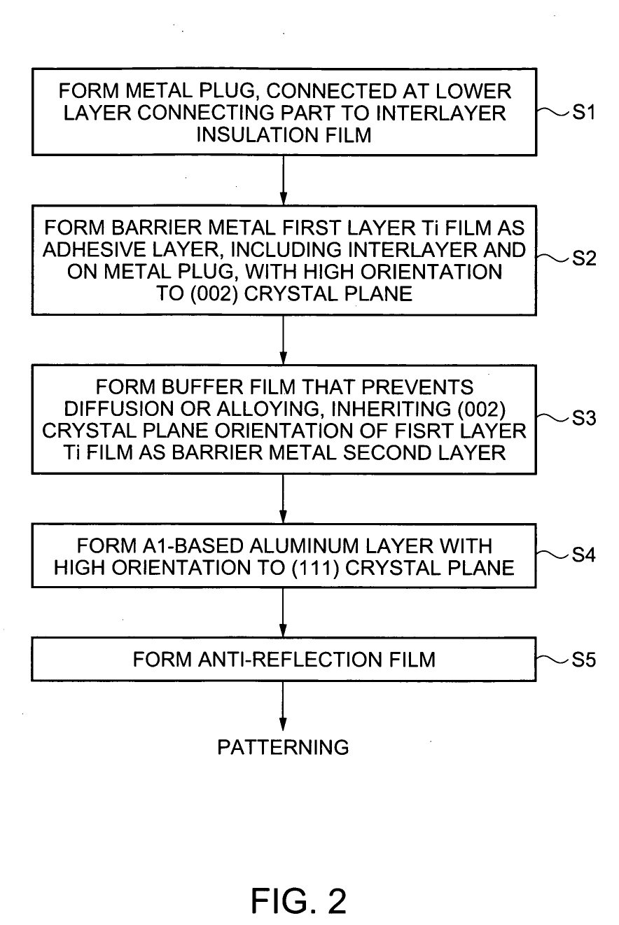

FIG. 2 is a flow chart that shows the manufacturing method of the semiconductor device in the configuration of FIG. 1. The description is made with reference to FIG. 1. The hole HL that penetrates through the given interlayer insulation film IL on the semiconductor substrate Waf, where the connecting part CNT on the lower layer is exposed, is formed. The barrier metal BMcnt is formed preliminarily inside the hole HL, and the plug metal is buried. For the plug metal, the burying of W (Tungsten) using the CVD method or the sputtering method is conducted. Subsequently, using etchback or a CMP (Chemical Mechanical Polishing) technique, the plug is flattened. Consequently, the metal plug PLG is formed (a processing S1).

The above-mentioned barrier metal BMcnt is not limited specifically. For example, it is possible to use the aforementioned stacked layer of the first Ti film M1 and the second TiN film M2. The descriptions are referred later. If the aforementioned layers of the first Ti film M1 and the second TiN film M2 are adopted, it is possible to form the barrier metal BMcnt with a desirable step coverage feature.

Including the interlayer insulation film IL and on the metal plug PLG, the Ti film M1, which is an adhesive layer of the first layer of the barrier metal BM, is formed so that the (002) crystal plane is oriented (a processing S2). The Ti film M1 is formed, for example by using the sputter technique, so that the (002) crystal plane is set with a high orientation. More specifically, it is a refinement of sputter device. For example, without the invention being limited, a collimation material is inserted into a sputter chamber, and the direction that atoms are beamed at is restricted. Alternatively, a chamber is made to be in a high voltage, and the pull of an atom ion is strengthened. A further alternative is, to deal with lowering the pressure of the chamber, as well as with making the distance between a substrate and a target larger. For example, when lowering the pressure of the chamber, the pressure of the chamber is set to around 4*10−2 Pa, and the distance between the substrate and the target is around 200 mm to 300 mm. That is to say, the (002) crystal plane of the Ti film has the lowest energy in the atomic arrangement of the Ti atoms, and its stimulatory effect of self-orientation is taken advantage of. With any of the above refinements, the Ti film M1 is formed so that the (002) crystal plane is set with a high orientation. The Ti film M1 is formed in the thickness of around 10 to 20 nm.

Hereafter, a buffer film that the prevents diffusion or alloying is formed on the Ti film M1 (a processing S3). Here, the TiN film is formed as the buffer film. It is desirable that the TiN film M2 is formed by employing the CVD (Chemical Vapor Deposition) method. For example, the CVD method by employing a reaction system of Ti (N(CH3)2)4+N2+H2 or TiC14+N2+H2 is used. The film thickness of the TiN film M2 is formed to be around 5 to 10 nm, which is thinner than that of the Ti film M1, and when formed, it takes a form of an amorphous conductive film. Subsequently, the TiN film M2 inherits the orientation of the Ti film M1, and comes to the state which is set to the (111) crystal plane with a high orientation. The orientation of TiN (111) crystal plane is extremely similar to the atomic arrangement of the Ti (002) crystal plane. Consequently, crystallographic information is inherited from the first Ti film M1 by the second TiN film M2. Since the TiN film M2 is extremely thin, there is a possibility that the (111) crystal plane will not emerge, but, at the very least, it takes a pattern that inherits the effect of the (002) crystal plane orientation of the Ti film M1.

Hereafter, the Al-based aluminum layer M3 is formed on the TiN film M2, using, for example, the sputter technique in the thickness of around 300 to 500 nm (a processing S4). The aluminum layer M3 is dependent on the orientation of either the TiN film M2 or the Ti film M1 under the TiN film M2, and takes a structure that is controlled with a high orientation to the (111) crystal plane. Hereafter, on the aluminum layer M3, the TiN film M4 is formed in the thickness of around 30 nm with sputtering as an anti-reflection film (a processing S5). Subsequently, through a photolithography process and an etching process, the given patterning is conducted for the metal wiring WR.

According to the manufacturing method of the semiconductor device in the present invention, the buffer film is formed over the Ti film with the crystal orientation to the (002) face, without deforming the crystallographic information of the Ti film. An aluminum-based conductive layer is affected by the orientation of either the buffer film or the Ti film under the buffer film, and is dependent on the orientation, consequently taking a pattern that is controlled with a high orientation to the (111) crystal plane. Consequently, there is a contribution to the improvement of the electromigration resistance.

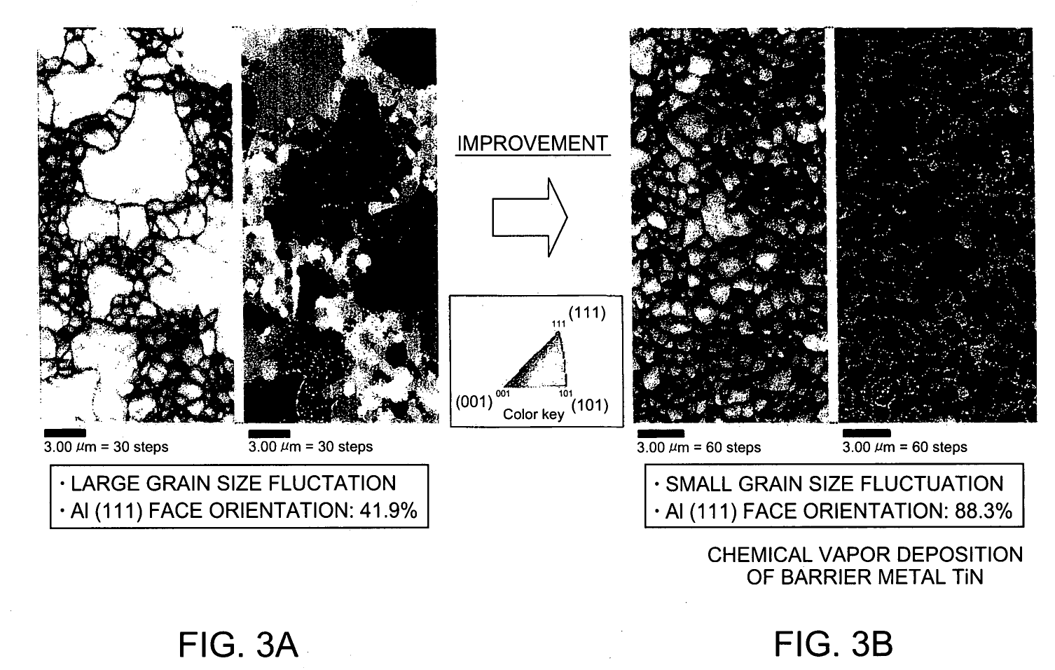

FIG. 3(a) is a magnified surface drawing that shows the grain size fluctuation as well as the level of the crystal orientation of the conventional aluminum wiring in the first embodiment of the present invention. The orientation ratio of the (111) crystal plane is 41.9%. The fluctuation of the grain size is also excessive.

FIG. 3(b) is a magnified surface drawing that shows the grain size fluctuation as well as the level of the crystal orientation of the aluminum wiring in the present invention. In other words, on the Ti film with the crystal orientation to the (002) face, the CVD-TiN film formed in a thin film that inherits the effect of the (002) crystal orientation of the Ti film, as mentioned above, is arranged. Consequently, in the aluminum wiring of the upper layer, the orientation ratio of the (111) crystal plane is 88.3%. The uniformity of the grain size is significantly improved. Due to the above, it is possible to form a wiring with a high electromigration resistance.

Moreover, while the TiN film M2 is employed as the buffer film, from the perspective of inheriting the effect of the (002) crystal orientation of the Ti film M1 during the thin-film formation, a similar effect can be expected by altering the thin-film formation with a buffer film of other substances, for example tantalum nitride (TaN) etc.

Furthermore, the TiN film M2, formed in a thin film as the buffer film, is formed by employing CVD method. However, if a uniform thin-film formation in the thickness of 10 nm is possible by employing the sputter technique, it is possible to draw the conclusion that a forming of a buffer film can be achieved without deforming the crystallographic information of the Ti film. Thus, a similar effect can be expected.

Further, the aluminum layer M3 is an Al-based wiring member, therefore the similar effect, not limited to the Al—Cu structure, can be expected with adopting the Al—Si structure and the Al—Si—Cu structure.

Further, it is also possible to form the TiN film M4 on the aluminum layer M3, not with the sputter deposition but with the CVD deposition. Alternatively, it is possible to install the anti-reflection film with the other substance.

In the metal wiring WR that includes the Ti film M1/TiN film M2 as the aforementioned barrier metal BM, as well as the aluminum layer M3 and the anti-reflection film TiN film M4, it is necessary to maintain caution in order to prevent the oxidation between the stacked layers. For provisioning, it is desirable to form all the stacked layers related to the metal wiring WR with the same devices (a multi-chamber system).

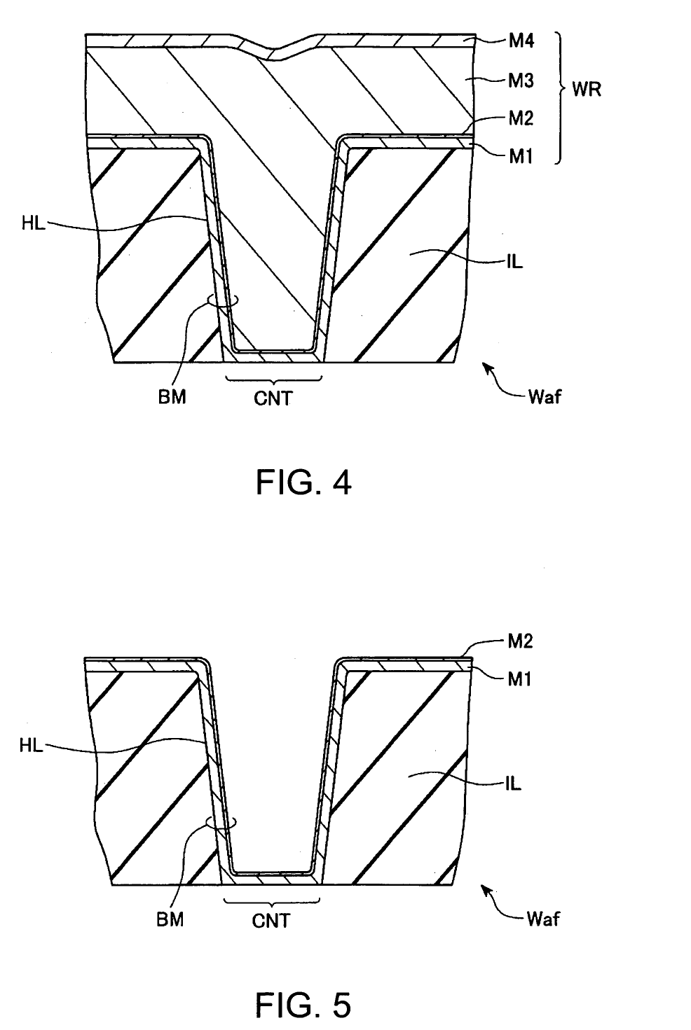

FIG. 4 is a sectional drawing that shows the stacked structure of the metal wiring in the second embodiment of the present invention. A metal wiring WR, in relation to multiple elements (not shown) formed on the semiconductor substrate Waf, constitutes an integrated circuit. For example, the metal wiring WR is composed so as to be patterned on the interlayer insulation film IL having the barrier metal BM as foundation, as well as to be connected to the connecting part CNT. At the connecting part CNT, the metal wiring WR that includes the aforementioned barrier metal BM is buried directly in the hole HL installed in the interlayer insulation film IL.

As for the metal wiring WR, it is the same as the first embodiment. That is to say, the orientation of the bottom layer of the metal wiring WR is important. The Ti film M1, as the first layer of the barrier metal BM, is set to the (002) crystal plane with a high orientation. The second layer TiN film M2 is thinner than that of the Ti film M1, and inherits the orientation of the Ti film M1. It is desirable to set the second layer TiN film M2 to the (111) crystal plane with a high orientation. The orientation of the TiN (111) crystal plane is extremely similar to the atomic arrangement of the Ti (002) crystal plane. Consequently, crystallographic information is inherited from the first Ti film M1 by the second TiN film M2. Moreover, the aluminum layer M3 has the Al—Cu structure that contains a very small quantity of Cu (about 0.5%) in the aluminum.

The TiN film M2 is, as in the first embodiment, the CVD-TiN film formed to be thin by employing chemical vapor deposition method. While the thickness of the Ti film M1 is around 10 to 20 nm, the thickness of the TiN film M2 is thinner than that of the Ti film M1, around 5 to 10 nm. Due to the above, it is possible to form the barrier metal BM with a desirable step coverage feature. Since the TiN film M2 is extremely thin, there is a possibility that the (111) crystal plane will not emerge, but, at the very least, it takes a pattern that inherits the effect of the (002) crystal plane orientation of the Ti film M1.

On the barrier metal BM, the aluminum layer M3 is formed in the thickness of around 300 to 500 nm. The aluminum layer M3 is dependent on the orientation of either the TiN film M2 or the Ti film M1 under the TiN film M2, and takes a pattern that is controlled with a high orientation to the (111) crystal plane. On the aluminum layer M3, the TiN film M4 is formed in the thickness of around 30 nm as the anti-reflection film.

FIG. 5 is a sectional drawing that shows the mid-flow process of the manufacturing method of the semiconductor device in the configuration of FIG. 4 (or FIG. 1). The main point is the same as the first embodiment. The hole HL that penetrates through the interlayer insulation film IL where the connecting part CNT is exposed is formed. Hereafter, the first layer Ti film MI of the barrier metal BM is formed so that the (002) crystal plane is oriented. The method for controlling orientation of the (002) crystal plane of the Ti film M1 is achieved with the method corresponding to the sputter device as described in the first embodiment. Hereafter, the buffer film (TiN film M2) that prevents diffusion or alloying is formed on the Ti film M1. The TiN film M2 is, as in the first embodiment, formed thinner than the Ti film M1 by employing the CVD method. It is important that the crystallographic information is inherited from the first Ti film M1 by the second TiN film M2. Due to the above, it is possible to form the barrier metal BM with a desirable step coverage feature.

Hereafter, the Al-based aluminum layer M3 is formed with sputtering on the TiN film M2, so that the hole HL is buried. The aluminum layer M3 is dependent on the orientation of either the TiN film M2 or the Ti film M1 under the TiN film M2, and takes a pattern that is controlled with a high orientation to the (111) crystal plane. Subsequently, on the aluminum layer M3, the TiN film M4 is formed with sputtering as the anti-reflection film.

Alternatively, for example, if W (tungsten) is embedded so as to bury the hole HL, and flattened by using etchback or Chemical Mechanical Polishing (CMP) techniques, then the metal plug PLG having the barrier metal BMcnt is completed. The barrier metal BMcnt is a thin film with a desirable step coverage feature, therefore effective flattening can be expected.

With the method and structure of the aforementioned embodiment, a similar effect can be obtained. That is to say, the CVD-TiN film M2 is formed on the Ti film as a buffer film with a crystal orientation of (002) face, without deforming the crystallographic information of the Ti film The aluminum layer M3 is dependent on the orientation of either the TiN film M2 or the Ti film M1 under the TiN film M2, and takes a pattern that is controlled with a high orientation to the (111) crystal plane. As a result, as shown in FIG. 3(b), a wiring formation, that has the aluminum wiring controlled with a high orientation to the (111) crystal plane, with a significantly improved uniformity of the grain size, thus having a high electromigration resistance, is possible.

It is important that the buffer film that prevents diffusion or alloying is formed without deforming the crystallographic information of the Ti film with the (002) crystal plane orientation. Hence, the aluminum layer of the upper layer is affected by the orientation of the barrier metal BM, and takes a pattern that is controlled with a high orientation to the (111) crystal plane. Consequently, in the second embodiment, as in the first embodiment, if the orientation of the barrier metal BM is inherited and affected, it is possible, except for CVD, to employ techniques that enable a thin-film formation with other substances as a buffer film, for example, tantalum nitride (TaN), or a technique that enables a uniform thin-film formation as a buffer film.

As described above, with the present invention, the crystal orientation of the Ti film is set to the (002) face with a high orientation, and over it, the buffer film, that prevents diffusion or alloying so as to inherit the crystallographic information of the Ti film, is formed. The aluminum-based conductive layer on the buffer film is dependent on the orientation of either the buffer film or the Ti film under the buffer film, and takes a structure that is controlled with a high orientation to the (111) crystal plane, with a high electromigration resistance. As a result, it is possible to provide the semiconductor device and the manufacturing method thereof, which forms a thin-film barrier metal that does not affect neither the existing process nor the wiring resistance as much as possible, and has the aluminum-based highly reliable wiring structure which sets a (111) crystal plane with a high orientation.

1. A semiconductor device comprising:
a wiring member that constitutes an integrated circuit in relation to multiple elements formed on a semiconductor substrate;
wherein the wiring member comprises a an aluminum-based conductive layer with a barrier metal layer including a titanium film as a first layer, as arranged with a high orientation to a (002) crystal plane and a buffer film as a second layer that inherits the orientation of the titanium film as well as having a film thickness that prevents diffusion or alloying, where the conductive layer is controlled with a high orientation to a (111) crystal plane.

2. The semiconductor device, according to claim 1, further comprising:
an interlayer insulation film; and
a part of a hole that penetrates through the insulation film and exposes a conductive base;
wherein the wiring member is formed on the insulation film and on the hole.

3. The semiconductor device, according to claim 1, further comprising:
an interlayer insulation film;
a part of a hole that penetrates through the insulation film and exposes a conductive base; and
a connecting plug buried in the hole;
wherein the wiring member is formed on the insulation film and on the connecting plug.

4. The semiconductor device according to claim 3, wherein the connecting plug is arranged with the barrier metal.

5. A semiconductor device comprising:
a wiring member that constitutes an integrated circuit in relation to multiple elements formed on a semiconductor substrate;
wherein the wiring member comprises an aluminum-based conductive layer with a barrier metal layer including a titanium film as the first layer having a (002) crystal plane, and a titanium nitride film as the second layer formed by chemical vapor deposition method, of which a film thickness is smaller than that of the titanium film, where the conductive layer is controlled with a high orientation to a (111) crystal plane.

6. The semiconductor device, according claim 5, further comprising:
an interlayer insulation film; and
a part of a hole that penetrates through the insulation film and exposes a conductive base;
wherein the wiring member is formed on the insulation film and on the hole.

7. The semiconductor device, according to claim 5, further comprising:
an interlayer insulation film;
a part of a hole that penetrates through the insulation film and exposes a conductive base; and
a connecting plug buried in the hole;
wherein the wiring member is formed on the insulation film and on the connecting plug.

8. The semiconductor device according to claim 7, wherein the connecting plug is arranged with the barrier metal.

9. A semiconductor device comprising:
a wiring member that constitutes an integrated circuit in relation to multiple elements formed on a semiconductor substrate;
wherein the wiring member comprises an aluminum-based conductive layer with a barrier metal layer including a titanium film as the first layer having a (002) crystal plane, and a titanium nitride film as the second layer that inherits the orientation of the titanium film, where the conductive layer is controlled with a high orientation to a (111) crystal plane that is affected by the orientation of the titanium film.

10. The semiconductor device, according to claim 9, further comprising:
an interlayer insulation film; and
a part of a hole that penetrates through the insulation film and exposes a conductive base;
wherein the wiring member is formed on the insulation film and on the hole.

11. The semiconductor device, according to claim 9, further comprising:
an interlayer insulation film;
a part of a hole that penetrates through the insulation film and exposes a conductive base; and
a connecting plug buried in the hole;
wherein the wiring member is formed on the insulation film and on the connecting plug.

12. The semiconductor device according to claim 11, wherein the connecting plug is arranged with the barrier metal.

13. A method of manufacturing a semiconductor device that forms a wiring member that relates to multiple elements on a given layer of a semiconductor substrate, wherein for the wiring member, the method of manufacturing the semiconductor device comprising the steps of:
forming a titanium film as a first layer of a barrier metal with a high orientation to a (002) crystal plane;
forming a buffer film that prevents diffusion or alloying as a second layer of the barrier metal so that an orientation of the titanium film is inherited; and
forming an aluminum-based conductive layer on the buffer film as a main part of the wiring member, that is controlled with a high orientation to a (111) crystal plane by, at least, being affected by the orientation of the titanium film.

14. The method of manufacturing the semiconductor device according to claim 13, wherein a sputtering method is used for the titanium film.

15. The method of manufacturing the semiconductor device according to claim 13, wherein the titanium nitride film is formed with a chemical vapor deposition method for the buffer film.

16. The method of manufacturing the semiconductor device according to claim 13, wherein the titanium nitride film that is thinner than the titanium film is formed for the buffer film.
